(19) United States
(12) Patent Application Publication
(10) Pub. No.: US 2014/0055160 A1
(43) Pub. Date: Feb. 27, 2014

(54) APPARATUS AND METHOD FOR INSPECTION OF MARKING

(71) Applicant: Korea Hugle Electronics Inc., Seoul (KR)

(72) Inventors: Young Mok Kim, Seoul (KR); Hyoung Woo Bae, Seoul (KR)

(73) Assignee: Korea Hugle Electronics Inc., Seoul (KR)

(21) Appl. No.: 13/967,646

(22) Filed: Aug. 15, 2013

(30) Foreign Application Priority Data
Aug. 24, 2012 (KR) 10-2012-0092689

(51) Int. Cl. G01R 31/28

(52) U.S. Cl. CPC G01R 31/28
USPC 324/759.02

(57) ABSTRACT

An apparatus and method for inspecting whether marking of a target chip in a wafer has been performed normally are provided. The apparatus includes a voltage application detector which detects application of a voltage to an external circuit, an image pickup unit which captures an image, and a controller which controls the image pickup unit to capture an image at at least one predetermined point when the application of the voltage is detected by the voltage application detector and determines whether the marking of the target chip has been performed normally based on the captured image. Accordingly, extra time is not required to inspect whether the marking of the target chip in the wafer has been performed normally and the inspection is performed without using a prober operation program.

### BACKGROUND OF THE INVENTION

1. Field of the Invention

The present invention relates to marking inspection, and more particularly, to an apparatus and method for inspecting whether a target chip in a wafer is normally marked.

2. Background of the Related Art

Generally, semiconductor manufacturing processes includes a process of inspecting the electrical characteristics of chips formed in a wafer. This electrical characteristic inspection is performed using a prober and a tester.

The prober moves a wafer freely to inspect the electrical characteristics of chips in the wafer. The prober is equipped with a probe card which connects a chip in the wafer to the tester.

During the electrical characteristic inspection, the prober moves a wafer to allow a chip in the wafer to contact a probe needle mounted at the probe card. At this time, the tester applies electricity to the chip through the probe needle. When the response of the chip to the electricity does not meet a predetermined standard, the tester determines the chip as a faulty one. When the inspection of the current chip is completed, the prober moves the wafer so that the next chip contacts the probe needle. The prober and the tester repeat these operations until inspection of every chip in the wafer is finished. The prober stores the coordinates of a position of each faulty chip in the wafer.

When the electrical characteristic inspection is completed, a marking process is performed on faulty chips in the wafer. The marking process is performed using the prober and a marking means.

In the marking process, the prober reads the coordinates of a position of a faulty chip in the wafer. The prober moves the wafer so that the chip corresponding to the coordinates is located below the marking means mounted at the prober. The marking means is for marking a target chip positioned below it. For instance, the marking means is a means that discharges ink for semiconductor to form a dot on the target chip. The prober applies a driving voltage to the marking means. Then, the marking means operates to form a mark on the target chip, thereby marking the faulty chip. When marking of the current faulty chip is completed, the prober moves the wafer so that the next faulty chip is located below the marking means. The prober and the marking means repeat these operations until all of faulty chips in the wafer are marked.

After the marking process is completed, a process of dicing the wafer into individual chips is performed. After the dicing process is completed, the chips are classified. In the classification, a vision system is used to determine whether each of the chips has a mark. Chips determined to have a mark are classified as faulty and chips determined to have no mark are classified as good.

When marking of a faulty chip in the wafer is not performed normally, it may happen that a faulty chip is wrongly classified as good one in the classification. For instance, when a mark does not exist at all on a faulty chip, when a mark on a faulty chip is smaller than a predetermined size, or when a mark is not located at a predetermined position on a faulty chip, the faulty chip may be wrongly classified as goon one. To prevent this, whether marking of a faulty chip in the wafer has been normally performed can be inspected during the marking process. Conventionally, the marking inspection is performed using a prober and a camera.

According to one of conventional marking inspection methods, a prober sequentially marks all faulty chips using a marking means while moving a wafer. Thereafter, the prober sequentially inspects all faulty chips, on which marking has been completed, using a camera while moving the wafer again. In the inspection process, the prober captures an image of the faulty chips, on which marking has been completed, using the camera and inspects the marking based on the captured image. However, this method has a problem in that an extra long time is required for the marking inspection after the marking process is completed.

According to another one of the conventional marking inspection methods, a prober temporarily halts a marking process after it marks a current faulty chip using a marking means. During the halt, the prober captures an image of the current faulty chip using a camera and inspects the marking based on the captured image. Only after the inspection is completed, the prober moves the wafer to start the marking of the next faulty chip. The prober repeats these operations until all faulty chips in the wafer are marked and inspected. However, this method also has a problem in that an extra waiting time is required for the marking inspection in addition to a time for the marking itself.

According to yet another one of the conventional marking inspection methods, a prober operation system is used. The prober operation system may be implemented by a personal computer. A prober operation program is installed in the prober operation system. The prober operation system communicates data, which are unique, with a prober and a camera using a communication method like General Purpose Interface Bus (GPIB) according to the prober operation program.

In this method, each time when the prober marks a faulty chip, the prober operation system transmits data instructing to capture an image to the camera. The prober operation system receives data of the image captured by the camera and inspects the marking based on the data.

In this method, the prober operation program is essentially necessary for the data communication and the marking inspection. However, it is substantially impossible for any manufacturers or users other than original manufacturers of the prober to interpret an operating system installed in the prober, and therefore, it is substantially impossible for other manufacturers or users to make the prober operation program for data communication with the prober.

Accordingly, for the marking inspection using this method, it must be required that a prober operation program for executing marking inspection has been developed by the manufacturer of a prober. Otherwise, it is impossible to perform the marking inspection using this method. In other words, it is a problem in that the prober operation program is not universal.

### SUMMARY OF THE INVENTION

The present invention provides an apparatus and method for inspecting whether marking of a target chip in a wafer has been normally performed without requiring extra time and a prober operation program.

According to an aspect of the present invention, there is provided an apparatus for inspecting whether marking of a target chip in a wafer has been performed normally. The apparatus includes a voltage application detector which detects application of a voltage to an external circuit, an image pickup unit which captures an image, and a controller which controls the image pickup unit to capture an image at at least one predetermined point when the application of the voltage is detected by the voltage application detector and determines whether the marking of the target chip has been performed normally based on the captured image.

According to another aspect of the present invention, there is provided a method of inspecting whether marking of a target chip in a wafer has been performed normally. The method includes detecting application of a driving voltage for the marking of the target chip to a marking means, capturing an image of the target chip at at least one point including a point after the target chip is marked in response to the detection, and determining whether the marking of the target chip has been performed normally based on the captured image.

According to another aspect of the present invention, there is provided a computer readable recording medium containing computer program codes for performing each step of the above-described method.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a marking inspection apparatus according to an embodiment of the present invention;

FIG. 2 is a flowchart of a marking inspection method according to an embodiment of the present invention;

FIG. 3 is a flowchart of the step capturing an image in the method illustrated in FIG. 2; and

FIG. 4 is a flowchart of the step determining in the method illustrated in FIG. 2.

### DETAILED DESCRIPTION OF THE PREFERRED EMBODIMENT

Hereinafter, embodiments of the present invention will be described in detail with reference to the attached drawings. The terminology used herein should not be limited to definitions in commonly used dictionaries but should be interpreted as having a meaning that is consistent with their meaning in the context of the relevant art and/or the present application based on the principle that an inventor is allowed to appropriately define the concept of terms to convey the invention in the best way.

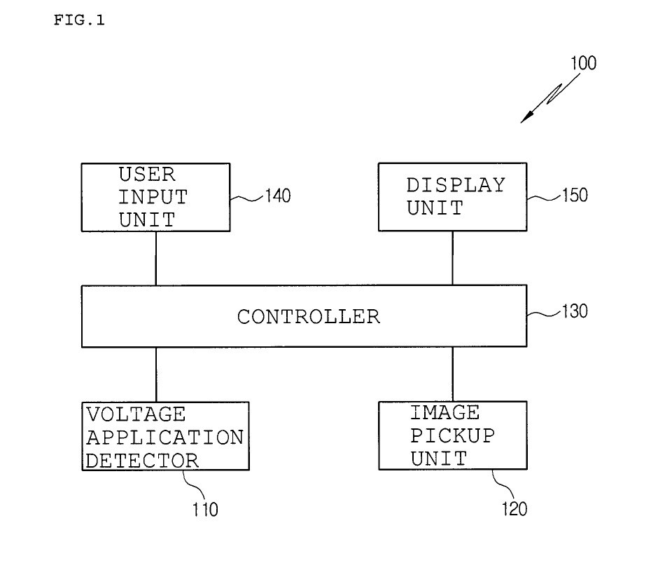

FIG. 1 is a block diagram of a marking inspection apparatus 100 according to an embodiment of the present invention. Referring to FIG. 1, the marking inspection apparatus 100 includes a voltage application detector 110, an image pickup unit 120, a controller 130, a user input unit 140, and a display unit 150.

Usually, the electrical characteristics of chips formed in a wafer are examined using a prober and a tester during semiconductor manufacturing processes. The prober stores coordinates of a position of each faulty chip in the wafer as a result of the examination.

Thereafter, the prober performs a marking operation on faulty chips in the wafer using a marking means in order to mark the faulty chips. In detail, the prober reads the coordinates of the faulty chip in the wafer. The prober moves the wafer so that a chip corresponding to the coordinates that have been read is located below the marking means mounted at the prober. The marking means is for marking a target chip positioned below the marking means. For instance, the marking means is a means that discharges ink for semiconductor to form a dot on the target chip. The prober applies a driving voltage to the marking means. Then, the marking means operates to form a mark on the target chip, thereby marking the faulty chip. When marking of the current faulty chip is completed, the prober moves the wafer so that the next faulty chip is located below the marking means. The prober repeats these operations until all of faulty chips in the wafer are marked.

The marking inspection apparatus 100 may be used to inspect whether the marking operation has been performed normally.

The voltage application detector 110 detects whether a voltage has been applied to an external circuit. The voltage application detector 110 may be connected to a circuit of an external apparatus and may detect whether the voltage has been applied to the circuit. The detection of voltage application is transmitted to the controller 130 through an input/output (I/O) cable or the like. In other words, a detected voltage may be used as an input signal of the controller 130. When the controller 130 receives the input signal from the voltage application detector 110, it controls the image pickup unit 120 to capture an image, which will be described later.

Usually, the prober applies a driving voltage to the marking means in order to drive the marking means to mark a target chip. For instance, the marking means is an ink discharging means and the prober applies a driving voltage of DC 24 V to a solenoid of the ink discharging means. The driving voltage may vary with the model and manufacturer of the prober. For example, it may be DC 36, 48, or 60 V.

The solenoid of the ink discharging means is usually exposed to the outside. The voltage application detector 110 may be directly connected to the solenoid and may detect the application of the driving voltage to the solenoid. For instance, the voltage application detector 110 may be directly connected to the solenoid by respectively coupling a female connector and a male connector to an end of a coil forming the solenoid and an end of the voltage application detector 110 and coupling the female connector with the male connector.

Usually, the prober includes a connector coupled to the solenoid of the ink discharging means. When the solenoid of the ink discharging means is not exposed to the outside, the voltage application detector 110 may be indirectly connected to the solenoid of the ink discharging means by coupling the connector of the voltage application detector 110 with the connector of the prober.

Meanwhile, the marking means, to which the driving voltage has been applied, operates to form a mark on a target chip.

The image pickup unit 120 captures an image. The image pickup unit 120 may be implemented by a camera. The image pickup unit 120 may be fixed at a specific position using a bracket so as to capture a target object. For instance, the image pickup unit 120 may be fixed to the prober to capture an image of a target chip of the marking means mounted at the prober. The image pickup unit 120 may include a lighting means to illuminate the target object.

When the voltage application is detected by the voltage application detector 110, the controller 130 controls the image pickup unit 120 to capture an image at at least one predetermined point. As described above, the voltage detected by the voltage application detector 110 may be used as an input signal to the controller 130 and the controller 130 controls the image pickup unit 120 to capture the image in response to the input signal.

The at least one image capturing point may be set to a default value in advance or may be set by a user. The user may set in advance the at least one image capturing point through the user input unit 140.

For instance, the at least one image capturing point may be set to a first point after the voltage application is detected by the voltage application detector 110 and a second point after the first point. At this time, the first point and the second point may be before and after, respectively, the target chip is marked by the marking means. In detail, the first point may be set to a time 30 ms after the voltage application is detected by the voltage application detector 110 and the second point may be set to a time 200 ms after the detection of the voltage application by the voltage application detector 110.

The controller 130 transmits a capture signal to the image pickup unit 120 to control the image pickup unit 120 to capture an image. The image pickup unit 120 captures an image in response to the capture signal. The image pickup unit 120 transmits data of the captured image to the controller 130.

For instance, when a voltage detected by the voltage application detector 110 is a driving voltage of the marking means mounted at the prober, the image pickup unit 120 is fixed so as to capture an image of a target chip of the marking means, and the image capturing points of the image pickup unit 120 are before and after the target chip is marked; the controller 130 acquires an image of the target chip before being marked and an image of the target chip after being marked through the image pickup unit 120.

The controller 130 may display the images captured by the image pickup unit 120 through the display unit 150.

The controller 130 determines whether the marking of the target chip has been performed normally based on the data received from the image pickup unit 120. The controller 130 may display a result of the determination through the display unit 150.

For instance, when an image captured at the first point is an image captured before the marking of the target chip and an image captured at the second point is an image captured after the marking, the controller 130 may process the image captured at the first point and the image captured at the second point to detect a difference therebetween. At this time, the controller 130 may binarize the captured images into black and white and then detect the difference, which corresponds to a trace of marking.

The controller 130 determines that the marking of the target chip has not been performed normally when the marking trace does not meet a predetermined standard. A user may set in advance the standard through the user input unit 140. For instance, the user may set a minimum size of the marking trace that can be determined normal or a position at which a normal marking trace is supposed to appear as the standard. The standard may be preset to a default value.

Based on the standard, the controller 130 determines that the marking of the target chip has not been performed normally when the marking trace is smaller than the predetermined size or when it does not appear at the predetermined position.

The controller 130 may measure X and Y values of the marking trace and compare the X and Y values with the predetermined standard to determine whether the marking has been performed normally.

When the controller 130 determines that the marking of the target chip has not been performed normally, it may display a warning signal or the like through the display unit 150. At this time, the controller 130 may also transmit an operation stop signal to the prober. The output signal of the controller 130 may be transmitted to the prober through an I/O cable or the like. Then, the operation of the prober is stopped in order to identify and resolve the cause of a problem. The display of the warning signal and the transmission of the operation stop signal, both may be carried out.

The controller 130 may additionally or alternatively perform other necessary operations when the abnormal marking of the target chip is determined.

The controller 130 may be implemented by a personal computer (PC).

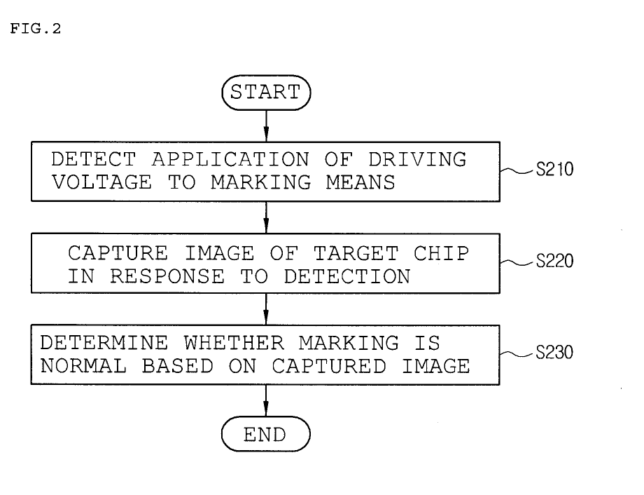

FIG. 2 is a flowchart of a marking inspection method according to an embodiment of the present invention. FIG. 2 shows a method of inspecting whether marking of a target chip in a wafer has been performed normally. The method may be performed by the marking inspection apparatus 100 illustrated in FIG. 1.

As described above, the electrical characteristics of chips formed in a wafer are examined using a prober and a tester during semiconductor manufacturing processes. The prober stores coordinates of a position of each faulty chip in the wafer as a result of the examination. Thereafter, the prober reads the coordinates of the faulty chip in the wafer. The prober moves the wafer so that the chip corresponding to the coordinates that have been read is located below the marking means mounted at the prober. Thereafter, the prober applies a driving voltage to the marking means. For instance, the marking means is an ink discharging means and the prober applies a driving voltage of DC 24 V to a solenoid of the ink discharging means. The driving voltage may be changed to DC 36, 48, or 60 V depending on the model and manufacturer of the prober.

When the driving voltage is applied to the marking means, the marking inspection apparatus 100 detects the application of the driving voltage in step S210.

In response to the detection of the driving voltage application, the marking inspection apparatus 100 captures an image of the target chip at at least one point including a time after the marking of the target chip in step S220. The marking inspection apparatus 100 may display the captured image.

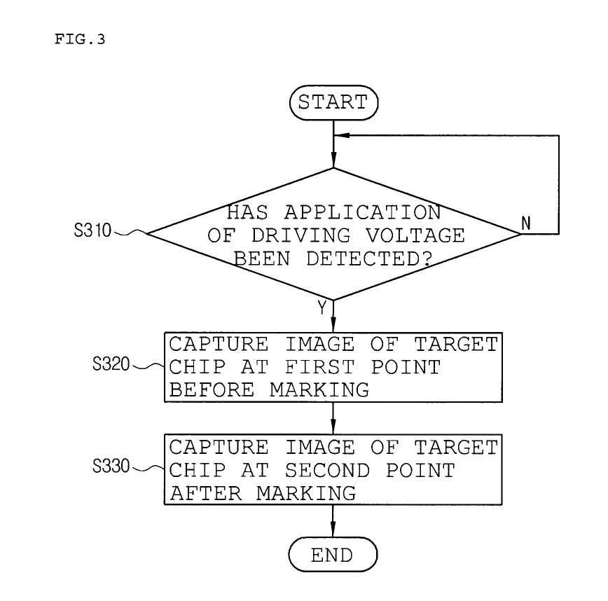

FIG. 3 is a flowchart of the capturing the image in step S220 illustrated in FIG. 2. Referring to FIG. 3, the capturing (S220) is performed when the application of the driving voltage to the marking means mounted at the prober is detected in step S310.

It is assumed that it takes 100 ms for the marking means to form a mark on the target chip in response to the driving voltage in the current embodiment. However, the marking time may vary with the model and manufacturer of the prober and the marking means.

The marking inspection apparatus 100 captures an image of the target chip at a first point before the marking of the target chip in step S320. For instance, the marking inspection apparatus 100 captures the image of the target chip at a time 30 ms after the application of the driving voltage to the marking means is detected.

The marking process by the prober and the marking means and the marking inspection process by the marking inspection apparatus 100 are performed independently from each other. For instance, the prober and the marking means do not halt the marking process for the image capturing of the marking inspection apparatus 100 at the first point. In the following operations, the prober and the marking means also perform the marking process regardless of the marking inspection process performed by the marking inspection apparatus 100. In other words, the prober and the marking means do not recognize the marking inspection process performed by the marking inspection apparatus 100.

By the time about 100 ms elapses since the detection of the driving voltage application to the marking means, a mark is formed by the marking means on the target chip, so that a faulty chip is marked.

After operations for the marking of the current faulty chip are completed, the prober moves the wafer and applies the driving voltage to the marking means again to mark the next faulty chip. However, it takes a certain time until the driving voltage is reapplied to the marking means after the current faulty is marked.

The marking inspection apparatus 100 captures an image of the target chip at a second point after the marking of the target chip in step S330. The second point is between the time when the mark is formed on the target chip and the time when the prober applies the driving voltage to the marking means to mark the next target chip. For instance, the marking inspection apparatus 100 captures the image of the target chip 200 ms after the application of the driving voltage to the marking means is detected.

Referring back to FIG. 2, the marking inspection apparatus 100 determines whether the marking of the target chip has been performed normally based on the captured images in step S230. The marking inspection apparatus 100 may display the result of the determination.

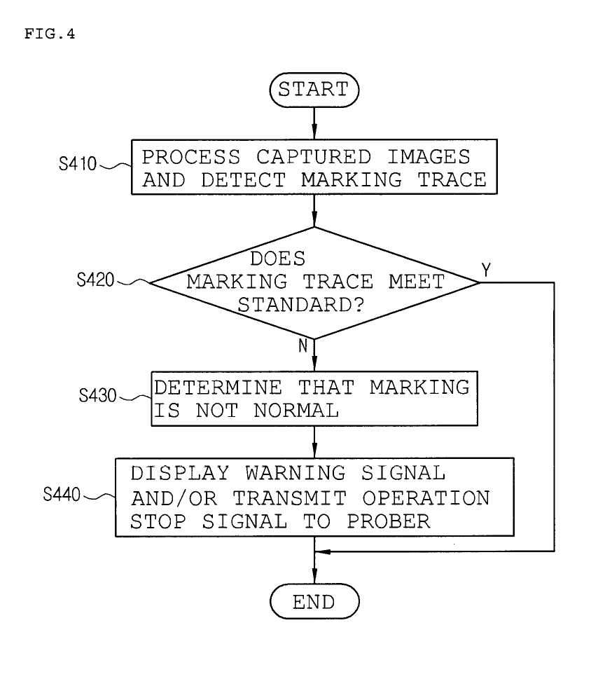

FIG. 4 is a flowchart of the determining in step S230 illustrated in FIG. 2. Referring to FIG. 4, the marking inspection apparatus 100 processes the captured images and detects a marking trace in step S410. In detail, the marking inspection apparatus 100 processes the image captured at the first point and the image captured at the second point and it detects the marking trace. At this time, the marking inspection apparatus 100 may binarize the images into black and white and then detect a difference between the binarized images to detect the marking trace.

The marking inspection apparatus 100 determines whether the marking trace meets a predetermined standard in step S420. The standard may be set by a user in advance. For instance, the standard is a minimum size of the marking trace that can be determined normal or a position at which a normal marking trace is supposed to appear. The standard may be set to a default value.

When the marking trace does not meet the predetermined standard, the marking inspection apparatus 100 determines that the marking of the target chip has not been performed normally in step S430. For instance, the marking inspection apparatus 100 determines that the marking of the target chip has not been performed normally when the marking trace is smaller than the predetermined size or when the marking trace does not appear at the predetermined position.

The marking inspection apparatus 100 may measure X and Y values of the marking trace and compare the X and Y values with the predetermined standard to determine the normality or abnormality of the marking.

When the marking of the target chip is determined abnormal, the marking inspection apparatus 100 may display a warning signal and/or transmit an operation stop signal to the prober in step S440. When the operation stop signal is transmitted to the prober, the operation of the prober may be stopped to identify and resolve the cause of the abnormality.

The marking inspection apparatus 100 may additionally or alternatively perform other necessary operations when the marking of the target chip is determined abnormal.

The steps illustrated in FIGS. 2 through 4 are performed between a time when the application of the driving voltage for marking a current faulty chip to the marking means mounted at the prober is detected and a time when the prober applies the driving voltage to the marking means to mark a next faulty chip.

When operations for the marking of the current faulty chip are completed, the prober moves the wafer to locate the next faulty chip below the marking means and then applies the driving voltage to the marking means. Then, the steps illustrated in FIGS. 2 through 4 are repeated with respect to the next faulty chip. The repetition is continued until the prober and the marking means finish marking all faulty chips.

As described above, the prober and the marking means perform the marking process regardless of the marking inspection process performed by the marking inspection apparatus 100. In other words, the prober and the marking means do not recognize the marking inspection process performed by the marking inspection apparatus 100 and the marking inspection process performed by the marking inspection apparatus 100 does not influence the marking process performed by the prober and the marking means. Accordingly, time delay that may occur due to the marking inspection process is prevented.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion.

According to some embodiments of the present invention, an additional time is not required to inspect whether marking of a target chip in a wafer has been performed normally. Therefore, time required for semiconductor manufacturing is reduced.

In addition, the inspection can be performed without using a prober operation program. Accordingly, even though there is no prober operation program that has been developed by the manufacturer of a prober for the execution of the marking inspection, the marking inspection can be performed without requiring extra time.

While this invention has been particularly shown and described with reference to preferred embodiments thereof, it will be understood by those skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. An apparatus for inspecting whether marking of a target chip in a wafer has been performed normally, the apparatus comprising:
a voltage application detector configured to be connected to a marking means, which marks the target chip, and to detect whether a driving voltage has been applied to the marking means;
an image pickup unit configured to capture an image; and
a controller configured to control the image pickup unit to capture an image at at least one predetermined point when application of the driving voltage is detected by the voltage application detector and to determine whether the marking of the target chip has been performed normally based on the captured image.

2. The apparatus of claim 1, wherein when the application of the driving voltage is detected by the voltage application detector, the controller controls the image pickup unit to capture an image at a first point and to capture an image at a second point following the first point.

3. The apparatus of claim 2, wherein the controller processes the image captured at the first point and the image captured at the second point, detects a difference between the images, and determines that the marking of the target chip has not been performed normally when the difference does not meet a predetermined standard.

4. The apparatus of claim 3, wherein the predetermined standard is about at least one of a size and a position based on which a marking trace is determined normal.

5. The apparatus of claim 1, wherein the marking is discharging an ink to form a dot in a predetermined size at a predetermined position on the target chip.

6. A method of inspecting whether marking of a target chip in a wafer has been performed normally, the method comprising:
detecting application of a driving voltage for the marking of the target chip to a marking means;
capturing an image of the target chip at at least one point including a point after the target chip is marked in response to the detection; and
determining whether the marking of the target chip has been performed normally based on the captured image.

7. The method of claim 6, wherein the capturing comprises:
capturing an image of the target chip at a first point before the target chip is marked; and
capturing an image of the target chip at a second point after the target chip is marked.

8. The method of claim 7, wherein the determining comprises:
processing the image captured at the first point and the image captured at the second point and detecting a marking trace; and
determining that the marking of the target chip has not been performed normally when the marking trace does not meet a predetermined standard.

9. The method of claim 8, wherein the predetermined standard is about at least one of a size and a position based on which the marking trace is determined normal.

10. The method of claim 6, wherein the marking is discharging an ink to form a dot in a predetermined size at a predetermined position on the target chip.

11. A computer readable recording medium containing computer program codes for performing each step in the method of any one of claims 6 through 10.
